(19) United States
(12) Patent Application Publication
(10) Pub. No.: US 2022/0173354 A1
(43) Pub. Date: Jun. 2, 2022

(54) DISPLAY DEVICE

(71) Applicant: Samsung Display Co., Ltd., Yongin-si (KR)

(72) Inventors: Kicheol Song, Suwon-si (KR); Youngmoon Kim, Asan-si (KR); Nari Ahn, Seongnam-si (KR)

(21) Appl. No.: 17/391,507

(22) Filed: Aug. 2, 2021

(30) Foreign Application Priority Data
Nov. 27, 2020 (KR) 10-2020-0162851

(51) Int. Cl. H01L 51/52; G09F 9/30

(52) U.S. Cl. CPC H01L 51/5246; H01L 51/5293; G09F 9/301

(57) ABSTRACT

Provided is a display device including a display module, a polarizing layer disposed on the display module, and an adhesive layer disposed between the display module and the polarizing layer, wherein at 60° C. and a relative humidity of from about 89% to about 96%, when a torque of 200 μN·m is applied to the adhesive layer for 10 minutes, the adhesive layer has a creep value of from about 10% to about 23%, and at 60° C. and a relative humidity of from about 89% to about 96%, the polarizing layer has a Young's modulus value of about 3000 MPa to about 5000 MPa.

### CROSS-REFERENCE TO RELATED APPLICATION

This U.S. non-provisional patent application claims priority under 35 U.S.C. § 119 to Korean Patent Application No. 10-2020-0162851, filed on Nov. 27, 2020 in the Korean Intellectual Patent Office, the entire contents of which are hereby incorporated by reference.

### BACKGROUND

The present inventive concept relates to a display device, and more particularly, to a display device including an adhesive layer.

Electronic devices such as a smart phone, a digital camera, a laptop computer, a navigation system, and a smart television which provide images to users include display devices for displaying images. The display devices generate images and provide the images to users through display screens.

In recent years, with the advancement of display device technology, various forms of display devices are under development. For example, flexible display devices which are foldable or rollable are being developed. The flexible display devices that are deformable into various forms may allow ease of portability and increase user friendliness.

The display device may include a display panel, a window disposed on the display panel, and a window protective layer disposed on the window. An adhesive layer may be disposed between the display panel and a polarizing layer, and the polarizing layer may be bonded to the display panel through the adhesive layer.

Meanwhile, the display panel may serve flexible operations such as folding or rolling.

### SUMMARY

The present disclosure provides a display device including an adhesive layer having improved reliability.

An embodiment of the inventive concept provides a display device including a display module, an anti-reflection layer disposed on the display module, and an adhesive layer disposed between the display module and the anti-reflection layer, wherein at 60° C. and a relative humidity of from about 89% to about 96%, when a torque of 943.9 μN·m is applied to the adhesive layer for 10 minutes, the adhesive layer has a creep value of from about 50% to about 120%, and at 60° C. and a relative humidity of from about 89% to about 96%, the anti-reflection layer has a Young's modulus value of from about 3000 MPa to about 5000 MPa.

In an embodiment, 10 minutes after the torque of 943.9 μN·m applied to the adhesive layer is removed, the adhesive layer may have a residual strain of from about 1.0% to about 9%, and a recovery rate of from 92% to 99%.

In an embodiment, when a torque of 200 μN·m is applied to the adhesive layer for 10 minutes, the adhesive layer may have a creep value of from about 10% to about 23%.

In an embodiment, 10 minutes after the torque of 200 μN·m applied to the adhesive layer is removed, the adhesive layer may have a residual strain of from about 0.1% to about 1.5%, and a recovery rate of about 94% to about 99%.

In an embodiment, when a torque of 2000 μN·m is applied to the adhesive layer for 10 minutes, the adhesive layer may have a creep value of from about 90% to about 400%.

In an embodiment, 10 minutes after the torque of 2000 μN·m applied to the adhesive layer is removed, the adhesive layer may have a residual strain of from about 4% to about 100%, and a recovery rate of from about 70% to about 99%.

In an embodiment, when a torque of 2300 μN·m is applied to the adhesive layer for 10 minutes, the adhesive layer may have a creep value of from about 100% to about 600%.

In an embodiment, 10 minutes after the torque of 2300 μN·m applied to the adhesive layer is removed, the adhesive layer may have a residual strain of from about 8% to about 200%, and a recovery rate of from about 40% to about 99%.

In an embodiment, at 25° C. and a relative humidity of from about 40% to about 50%, when a torque of 200 μN·m is applied to the adhesive layer for 10 minutes, the adhesive layer may have a creep value of from about 5% to about 30%, and at 25° C., the anti-reflection layer has a Young's modulus value of from about 8000 MPa to about 9000 MPa.

In an embodiment, at 25° C. and a relative humidity of from about 40% to about 50%, 10 minutes after the torque of 200 μN·m applied to the adhesive layer is removed, the adhesive layer may have a residual strain of from about 0.1% to about 2.5%, and a recovery rate of about 85% to about 99%.

In an embodiment, at 60° C. and a relative humidity of from about 40% to about 50%, when a torque of 200 μN·m is applied to the adhesive layer for 10 minutes, the adhesive layer may have a creep value of from about 8% to about 30%, and at 60° C. and a relative humidity of from about 40% to about 50%, the anti-reflection layer may have a Young's modulus value of about 5000 MPa to about 8000 MPa.

In an embodiment, at 60° C. and a relative humidity of from about 40% to about 50%, 10 minutes after the torque of 200 μN·m applied to the adhesive layer is removed, the adhesive layer may have a residual strain of from about 0.1% to about 3%, and a recovery rate of from about 85% to about 99%.

In an embodiment, when a frequency of 1 Hz and an axial force of 1.0 N are applied to the adhesive layer and the adhesive layer keeps a strain of 1%, the adhesive layer, at −20° C., may have a storage modulus value of from about 0.01 MPa to about 0.2 MPa, a loss elastic modulus value of from about 0.01 MPa to about 0.2 MPa, and a tan delta value of from about 0.5 to about 1.2. the tan delta value being defined as a loss modulus value divided by a storage modulus value, and at −20° C., the anti-reflection layer may have a Young's modulus value of from about 9000 MPa to about 11000 MPa.

In an embodiment, when a frequency of 1 Hz and an axial force of 1.0 N are applied to the adhesive layer and the adhesive layer is kept at a strain of 1%, the adhesive layer, at 25° C., may have a storage modulus value of from about 0.01 MPa to about 0.1 MPa, a loss elastic modulus value of from about 0.001 MPa to about 0.05 MPa, and a tan delta value of from about 0.1 to about 0.4. the tan delta value being defined as a loss modulus value divided by a storage modulus value, and at 25° C., the anti-reflection layer may have a Young's modulus value of from about 8000 MPa to about 9000 MPa.

In an embodiment, when a frequency of 1 Hz and an axial force of 1.0 N are applied to the adhesive layer and the adhesive layer is kept at a strain of 1%, the adhesive layer, at 60° C., may have a storage modulus value of from about 0.01 MPa to about 0.04 MPa, a loss elastic modulus value of from about 0.001 MPa to about 0.01 MPa, and a tan delta value of about 0.1 to about 0.4, the tan delta value being defined as a loss modulus value divided by a storage modulus value, and at 60° C. and a relative humidity of from about 40% to about 50%, the anti-reflection layer may have a Young's modulus value of about 5000 MPa to about 8000 MPa.

In an embodiment, when a frequency of 1 Hz and an axial force of 1.0 N are applied to the adhesive layer and the adhesive layer keeps a strain of 1%, the adhesive layer, at 85° C., may have a storage modulus value of from about 0.01 MPa to about 0.05 MPa, a loss elastic modulus value of from about 0.001 MPa to about 0.01 MPa, and a tan delta value of from about 0.1 to about 0.4, the tan delta value being defined as a loss modulus value divided by a storage modulus value, and at 85° C., the anti-reflection layer may have a Young's modulus value of 3000 MPa or less.

In an embodiment, the adhesive layer may include a silicone-based resin, an acrylic resin, or a urethane-based resin, and may have a thickness of from about 10 μm to about 70 μm.

In an embodiment, the adhesive layer may be in contact with each of the display module and the anti-reflection layer.

In an embodiment, the display device may further include a shock absorbing layer and a window disposed on the anti-reflection layer, wherein the shock absorbing layer may include a resin, and the window may include glass.

In an embodiment, the anti-reflection layer may be a polarizing layer.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a perspective view of a display device according to an embodiment of the present inventive concept;

FIG. 2 is a perspective view of a display device according to an embodiment of the present inventive concept;

FIG. 3 is a cross-sectional view of an embodiment corresponding to line I-I′ shown in FIG. 1 according to an embodiment of the present inventive concept;

FIG. 4 is a view illustrating the display device shown in FIG. 3 in an in-folded state according to an embodiment of the present inventive concept; and

FIG. 5 is a graph showing creep values and an initiator amount of each of Examples A1 and A2, and Comparative Example C1, as an example, at 60° C. and a humidity of 93% according to an embodiment of the present inventive concept.

### DETAILED DESCRIPTION

In the present description, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents.

The term “and/or,” includes all combinations of one or more of which associated configurations may define.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the inventive concept. The terms of a singular form may include plural forms unless the context clearly indicates otherwise.

In addition, terms such as “below,” “lower,” “above,” “upper,” and the like are used to describe the relationship of the configurations shown in the drawings. The terms are used as a relative concept and are described with reference to the direction indicated in the drawings.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

It should be understood that the terms “comprise”, or “have” are intended to specify the presence of stated features, integers, steps, operations, elements, components, or combinations thereof in the disclosure, but do not preclude the presence or addition of one or more other features, integers, steps, operations, elements, components, or combinations thereof.

Hereinafter, embodiments of the inventive concept will be described with reference to the accompanying drawings.

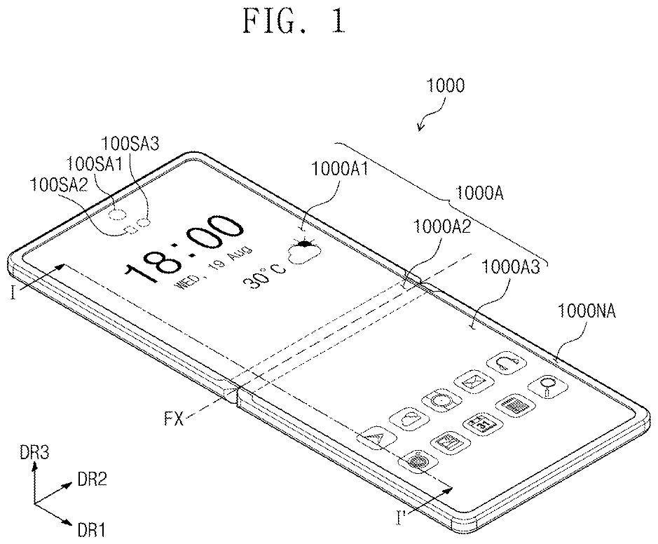

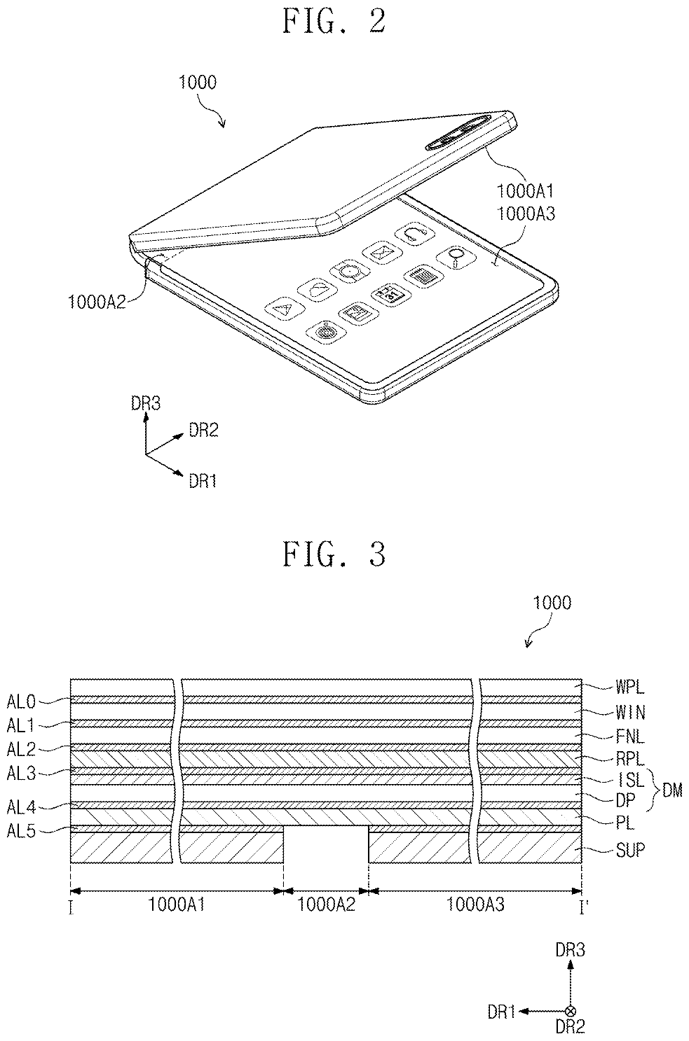

FIG. 1 is a perspective view of a display device 1000 according to an embodiment of the inventive concept. FIG. 2 is a perspective view of a display device 1000 according to an embodiment of the inventive concept. FIG. 1 illustrates the display device 1000 in an unfolded state, and FIG. 2 illustrates the display device 1000 in a folded state.

Referring to FIGS. 1 and 2, the display device 1000 may be a device activated according to electrical signals. For example, the display device 1000 may be a mobile phone, a tablet, a car navigation system, a game console, or a wearable device, but is not limited thereto. In FIGS. 1 and 2, a mobile phone is exemplarily illustrated as the display device 1000.

The display device 1000 may display images through an active area 1000A. FIG. 1 displays time via a clock widget and application icons as an example of images. When the display device 1000 is unfolded, the active area 1000A may include a plane defined by a first direction DR1 and a second direction DR2. A thickness direction of the display device 1000 may be parallel to a third direction DR3 crossing the first direction DR1 and the second direction DR2. Therefore, a front surface (or an upper surface) and a rear surface (or a lower surface) of the display device 1000 may be defined with respect to the third direction DR3. In an embodiment, the active area 1000A may be formed on the front surface of the display device 1000.

The active area 1000A may include a first area 1000A21, a second area 1000A2, and a third area 1000A3. The second area 1000A2 may be bent along a folding axis FX extending in the second direction DR2. Accordingly, the first area 1000A1 and the third area 1000A3 may be referred to as non-folding areas, and the second area 1000A2 may be referred to as a folding area. In addition, in FIG. 1, a peripheral area 1000NA adjacent to the active area 1000A is illustrated as an example, but the peripheral area 1000NA may be omitted if necessary.

When the display device 1000 is folded, the first area 1000A1 and the third area 1000A3 may face each other. Accordingly, in a fully folded state, the active area 1000A may not be exposed to the outside, which may be referred to as in-folding. However, this is presented as an example, and the operation of the display device 1000 is not limited thereto.

For example, in an embodiment of the inventive concept, when the display device 1000 is folded, the first area 1000A1 and the third area 1000A3 may oppose each other. Accordingly, in a folded state, the display device 1000 may be exposed to the outside, which may be referred to as out-folding.

The display device 1000 may be folded or unfolded in a manner of only any one of in-folding and out-folding. Alternatively, the display device 1000 may be folded or unfolded in a manner of both in-folding and out-folding. In this case, the same area of the display device 1000 (for example, the second area 1000A2) may be in-folded and out-folded. Alternatively, some areas of the display device 1000 may be in-folded, and some other areas may be out-folded.

In FIGS. 1 and 2, one folding area and two non-folding areas are illustrated as an example, but the number of folding areas and non-folding areas is not limited thereto. For example, the display device 1000 may include a plurality of non-folding areas of which a number is more than two, and a plurality of folding areas disposed in spaces between adjacent non-folding areas of the plurality of non-folding areas.

FIGS. 1 and 2 illustrate that the folding axis FX is parallel to a minor axis of the display device 1000 as an example, but the embodiment of the inventive concept is not limited thereto. For example, the folding axis FX may extend along a major axis of the display device 1000, for example, a direction parallel to the first direction DR1. In this case, the first area 1000A1, the second area 1000A2, and the third area 1000A3 may be sequentially arranged in the second direction DR2.

A plurality of sensing areas 100SA1, 100SA2, and 100SA3 may be defined in the display device 1000. In FIG. 1, three sensing areas 100SA1, 100SA2, and 100SA3 are illustrated as an example, but the number of the plurality of sensing areas 100SA1, 100SA2, and 100SA3 is not limited thereto.

The plurality of sensing areas 100SA1, 100SA2, and 100SA3 may include a first sensing area 100SA1, a second sensing area 100SA2, and a third sensing area 100SA3. The first to third sensing areas 100SA1, 100SA2, and 100SA3 may overlap electronic modules. The electronic modules may receive external inputs transmitted through the first sensing area 100SA1, the second sensing area 100SA2, or the third sensing area 100SA3, or may provide outputs through the first sensing area 100SA1, the second sensing area 100SA2, or the third sensing area 100SA3.

For example, the first sensing area 100SA1 may overlap a camera module, and the second sensing area 100SA2 and the third sensing area 100SA3 may overlap a proximity illuminance sensor. The present inventive concept, however, is not limited thereto.

The first sensing area 100SA1 may be surrounded by the active area 1000A, and the second sensing area 100SA2 and the third sensing area 100SA3 may be included in the active area 1000A. For example, the second sensing area 100SA2 and the third sensing area 100SA3 may display images. The first sensing area 100SA1, the second sensing area 100SA2, and the third sensing area 100SA3 each may have a greater transmittance than the active area 1000A. The first sensing area 100SA1 may have a greater transmittance than each of the second sensing area 100SA2 and the third sensing area 100SA3.

FIG. 3 is a cross-sectional view taken along line I-I′ of FIG. 1. Referring to FIG. 3, the display device 1000 may include a display panel DP, an input sensing layer ISL, an anti-reflection layer RPL, a functional layer FNL, a window WIN, a window protective layer WPL, a protective layer PL, a support portion SUP, first to fifth adhesive layers AL1 to AL5 and a window adhesive layer AL0. The display module DM may include the display panel DP and the input sensing layer ISL. The anti-reflection layer RPL, the functional layer FNL, the window WIN, and the window protective layer WPL may be disposed on the display module DM, and the protective layer PL and the support portion SUP may be disposed below the display module DM.

The display panel DP may be a flexible display panel. For example, the display panel DP may include a plurality of electronic elements disposed on a flexible substrate.

The display panel DP according to an embodiment of the inventive concept may be a light emitting display panel, and is not particularly limited. For example, the display panel DP may be an organic light emitting display panel or a quantum dot light emitting display panel. An emission layer of the organic light emitting display panel may include an organic light emitting material. An emission layer of the quantum dot light emitting display panel may include quantum dots, quantum rods, etc. Hereinafter, the display panel DP will be described as an organic light emitting display panel.

The input sensing layer ISL may be disposed on the display panel DP. The input sensing layer ISL may include a plurality of sensor units (not shown) configured to detect external inputs. The sensor units (not shown) may detect external inputs in a capacitive manner. The input sensing layer ISL may be directly disposed on the display panel DP when the display panel DP is manufactured. However, the embodiment of the inventive concept is not limited thereto, and the input sensing layer ISL may be separately manufactured as a panel from the display panel DP, and may be bonded to the display panel DP through an adhesive layer.

The anti-reflection layer RPL may be disposed between the input sensing layer ISL and the window WIN. The anti-reflection layer RPL may reduce reflectance of external light travelling from the top of the display device 1000 towards the display panel DP. For example, the anti-reflection layer RPL may include a retarder and/or a polarizer. In an embodiment, the polarizer may be a linear polarizer as an optical layer that linearly polarizes provided light in one direction. In an embodiment, the retarder may include a λ/2 retarder and a λ/4 retarder.

The functional layer FNL may be disposed on the anti-reflection layer RPL. In an embodiment, the functional layer FNL may include at least one of a shock absorbing layer or a hard coating layer.

The hard coating layer may have anti-fingerprint, anti-pollution, and scratch-resistant properties.

The shock absorbing layer may be a functional layer for protecting the display panel DP from external impacts. The shock absorbing layer may be prepared in the form of a stretched film. The shock absorbing layer may include or may be formed of a resin. For example, the shock absorbing layer may include or may be formed of a resin such as polyimide (PI) or polyethylene terephthalate (PET), and may be flexible. The shock absorbing layer may have elastic modulus of 1 GPa or greater.

The window WIN may be disposed on the functional layer FNL. The window WIN may protect the display panel DP, the input sensing layer ISL, the anti-reflection layer RPL, and the functional layer FNL from external scratches and impacts. The window WIN may be optically transparent.

The window WIN may include or may be formed of glass. For example, the window WIN may include or may be formed a chemically tempered glass substrate. When the window WIN is a chemically tempered glass substrate, the window WIN has increased mechanical rigidity while being thin in thickness, and the display device may have less chance of being damaged.

For example, the window WIN may have a thickness of from about 20 μm to about 80 μm. When the window WIN has a thickness less than about 20 μm, the window WIN has reduced rigidity, and the window WIN may be easily damaged due to external shocks (i.e., impacts). For example, the window WIN may be damaged when the display device 1000 is folded and unfolded. When the window WIN has a thickness greater than about 80 μm, the repulsive force against deformation increases, and the window WIN may be less flexible. For example, the window WIN may not be easily folded and unfolded.

However, the material of the window WIN is not limited thereto, and the window WIN may include or may be formed of a resin film, for example, a polyimide film.

The window WIN may have a multilayer structure or a single layer structure. For example, the window WIN may include or may be formed of a plurality of synthetic resin films bonded to each other through an adhesive, or a glass substrate and a synthetic resin film, which are bonded to each other through an adhesive.

The window protective layer WPL may be disposed on the window WIN. The window protective layer WPL may protect the window WIN. The window protective layer WPL may be optically transparent. Accordingly, images generated in the display panel DP may be provided to users through the window WIN and the window protective layer WPL.

The window protective layer WPL may be a film including or being formed of at least one resin among polyethylene terephthalate (PET), polybutylene terephthalate (PBT), polyethylene naphthalene (PEN), polycarbonate (PC), poly(methylmethacrylate (PMMA), polystyrene (PS), polyvinylchloride (PVC), polyethersulfone (PES), polypropylene (PP), polyamide (PA), modified polyphenylene ether (m-PPO), polyoxymethylene (POM), polysulfone (PSU), polyphenylene sulfide (PPS), polyimide, (PI), polyethyleneimine (PEI), polyether ether ketone (PEEK), polyamide imide (PAI), polyarylate (PAR), and thermoplastic polyurethane (TPU).

The protective layer PL may be disposed below the display panel DP. The protective layer PL may be defined as a protective substrate. The protective layer PL may protect a lower portion of the display layer DP. The protective layer PL may include or may be formed of a plastic material. For example, the protective layer PL may include or may be formed of polyethylene terephthalate (PET).

The support portion SUP may be disposed below the protective layer PL. The support portion SUP may support the display panel DP. The support portion SUP does not overlap the second area 1000A2 which is a folding area. The support portion SUP may overlap the first area 1000A1 and the third area 1000A3 which are non-folding areas.

The support portion SUP may include or may be formed of metal. For example, the support portion SUP may include or may be formed of stainless steel, aluminum, or an alloy thereof. The support portion SUP may have a greater strength than the display panel DP.

Although not shown, a cushion layer may be disposed between the protective layer PL and the support portion SUP. The cushion layer may absorb external shocks applied to the lower portion of the display device 1000 to protect the display panel DP. The cushion layer may include or may be formed of a foam sheet having a predetermined elasticity.

A window adhesive layer AL0 may be disposed between the window protective layer WPL and the window WIN. In an embodiment, the window adhesive layer AL0 may be in contact with each of the window protective layer WPL and the window WIN. The window protective layer WPL and the window WIN may be bonded to each other through the window adhesive layer AL0.

The first adhesive layer AL1 may be disposed between the window WIN and the functional layer FNL. In an embodiment, the first adhesive layer AL1 may be in contact with each of the window WIN and the functional layer FNL. The functional layer FNL and the window WIN may be bonded to each other through the first adhesive layer ALL

The second adhesive layer AL2 may be disposed between the functional layer FNL and the anti-reflection layer RPL. In an embodiment, the second adhesive layer AL2 may be in contact with each of the functional layer FNL and the anti-reflection layer RPL. The functional layer FNL and the anti-reflection layer RPL may be bonded to each other through the second adhesive layer AL2.

The third adhesive layer AL3 may be disposed between the anti-reflection layer RPL and the display module DM. In an embodiment, the third adhesive layer AL3 may be in contact with each of the anti-reflection layer RPL and the display module DM. The anti-reflection layer RPL and the input sensing layer ISL of the display module DM may be bonded to each other through the third adhesive layer AL3.

The fourth adhesive layer AL4 may be disposed between the display module DM and the protective layer PL. In one embodiment, the fourth adhesive layer AL4 may be in contact with each of the display module DM and the protective layer PL. The display panel DP of the display module DM and the protective layer PL may be bonded to each other through the fourth adhesive layer AL4.

The fifth adhesive layer AL5 may be disposed between the protective layer PL and the support portion SUP. In an embodiment, the fifth adhesive layer AL5 may be in contact with each of the protective layer PL and the support portion SUP. The protective layer PL and the support portion SUP may be bonded to each other through the fifth adhesive layer AL5.

For example, the window adhesive layer AL0 and the first to fifth adhesive layers AL1 to AL5 may be a transparent adhesive layer such as a pressure sensitive adhesive film (PSA), an optically clear adhesive film (OCA), or an optically clear adhesive resin (OCR). For example, the window adhesive layer AL0 and the first to fifth adhesive layers AL1 to AL5 may be a pressure sensitive adhesive film (PSA). However, the embodiment of the inventive concept is not limited thereto.

The window adhesive layer AL0 and the first to fifth adhesive layers AL1 to AL5 may include or may be formed of at least one of a silicone-based resin, an acrylic resin, and a urethane-based resin. For example, the first to fifth adhesive layers AL1 to AL5 may be formed of an acrylic resin, and the window adhesive layer AL0 and the first to fifth adhesive layers AL1 to AL5 may have a glass transition temperature of about −39° C. or less. Each of the window adhesive layer AL0 and the first to fifth adhesive layers AL1 to AL5 may have a thickness of from about 10 μm to about 70 μm.

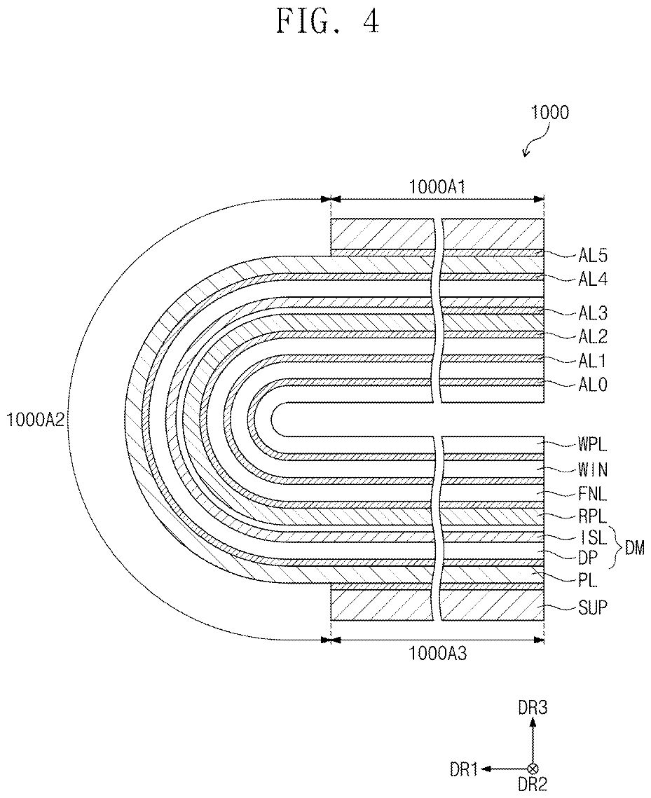

FIG. 4 is a view illustrating the display device shown in FIG. 3 in an in-folded state.

Referring to FIG. 4, the display device 1000 may be in-folded along a folding axis FX. The second area 1000A2 is bent such that the first area 1000A1 and the third area 1000A3 may face each other. The first area 1000A1 and the third area 1000A3 overlapping the support portion SUP may remain in a flat state.

The display device 1000 may change from the first state of being flat illustrated in FIG. 3 to the second state of being folded illustrated in FIG. 4, or may change from the second state to the first state. This folding action may be performed repeatedly.

For the folding action of the display device 1000, the window protective layer WPL, the window WIN, the functional layer FNL, the anti-reflection layer RPL, the input sensing layer ISL, the display panel DP, the protective layer PL, the window adhesive layer AL0, and the first to fifth adhesive layers AL1 to AL5 may have flexible properties.

When the folding action is repeatedly performed, the stress generated in the second area 1000A2 may affect (e.g., break or deform) the window adhesive layer AL0 and the first to fifth adhesive layers AL1 to AL5. However, the window adhesive layer AL0 and the first to fifth adhesive layers AL1 to AL5 according to an embodiment of the inventive concept have high elasticity, low strains, and high recovery rates, and the window adhesive layer AL0 and the first to fifth adhesive layers AL1 to AL5 each may keep elastic and recovery properties, and the first to fifth adhesive layers AL1 to AL5 each may be less deformed.

(Evaluation 1 of Adhesive Layer Properties)

In the evaluation of the adhesive layer properties of an embodiment, the elasticity, strain, and recovery rate of the third adhesive layer AL3 are evaluated. The window adhesive layer AL0, the first adhesive layer AL1, the second adhesive layer AL2, the fourth adhesive layer AL4, and the fifth adhesive layer AL5 may include or may be formed of the same material and have the same physical properties as the third adhesive layer AL3. Accordingly, as the third adhesive layer AL3, the window adhesive layer AL0, the first adhesive layer AL1, the second adhesive layer AL2, the fourth adhesive layer AL4, and the fifth adhesive layer AL5 may have high elasticity, low strains, and high recovery rates as well.

In Tables 1 to 6, the creep value, residual strain, and recovery rate of the third adhesive layer measured are shown. A third adhesive layer as Example may be the third adhesive layer AL3 disposed between the display module DM and the anti-reflection layer RPL in the display device 1000 according to an embodiment of the inventive concept. In the present embodiment, the anti-reflection layer RPL is a polarizing layer. A third adhesive layer as Comparative Example may be an adhesive layer disposed between a display module and a polarizing layer of a conventional display device.

In Table 1, the creep value, residual strain, and recovery rate of the third adhesive layer are measured at a torque of 943.9 μN·m which is applied to the third adhesive layer of Examples 1 to 4 and Comparative Example 1 in the test environment of 60° C. and a relative humidity of from about 89% to about 96%. Table 1 is a measurement of the creep values, residual strains, and recovery rates of the third adhesive layers of Examples 1 to 4 and Comparative Example 1. Conditions of 60° C. and a relative humidity of from about 89% to about 96% may be understood as a condition of high temperature and high humidity.

The creep values are measured as the strain of the adhesive layer when a torque of 943.9 μN·m is applied to the adhesive layer for 10 minutes. The residual strain is measured as the strain of the adhesive layer remaining 10 minutes after the torque of 943.9 μN·m applied to the adhesive layer is removed. The recovery rate may be defined as a rate in which the adhesive layer recovers 10 minutes after the torque of 943.9 μN·m applied to the adhesive layer is removed. Less creep values and residual strains, and greater recovery rates may indicate that the adhesive layer is less deformed against force or pressure.

Meanwhile, the creep values, residual strains, and recovery rates are values measured using a rheometer from TA Instruments. The present inventive concept is not limited thereto. For example, the values may be measured using a rheometer from another equipment supplier. The third adhesive layer is processed in the form of a disk having a diameter of 8 mm and a thickness of 800 μm as a measurement sample. However, this is presented as an example, and the third adhesive layer included in the display device of an embodiment may be separated from the display device and used as a measurement sample. For example, in a display device, a plurality of layers including a third adhesive layer is put in liquid nitrogen. After a predetermined period of time, the adhesive strength of the adhesive layer may decrease, and the plurality of layers may be separated from each other. Among the separated layers, layers adjacent to the third adhesive layer are put in an organic solvent, and after at least an hour, the solvent may be removed by evaporation and drying. An adhesive layer obtained from the process may be used as a test sample.

TABLE 1

| | | | Creep value | Residual strain | Recovery rate | |
|---|---|---|---|---|---|---|
| Item | | | (%) | (%) | (%) | Humidity |
| Example 1 | Number of | 1 | 95.51 | 4.10 | 95.71 | 94.02 |
| | measurements | 2 | 97.68 | 4.44 | 95.45 | 95.10 |
| | | 3 | 96.97 | 6.52 | 93.28 | 93.16 |
| Example 2 | Number of | 1 | 102.40 | 5.20 | 94.92 | 93.93 |
| | measurements | 2 | 106.48 | 6.56 | 93.84 | 94.50 |
| | | 3 | 103.64 | 5.30 | 94.89 | 94.15 |
| Example 3 | Number of | 1 | 56.34 | 1.48 | 97.37 | 93.55 |
| | measurements | 2 | 57.14 | 1.39 | 97.57 | 92.72 |
| | | 3 | 56.59 | 1.34 | 97.62 | 93.32 |
| Example 4 | Number of | 1 | 66.92 | 2.15 | 96.79 | 94.65 |
| | measurements | 2 | 57.99 | 1.50 | 97.41 | 93.81 |
| | | 3 | 55.96 | 1.38 | 97.53 | 94.11 |
| Comparative | Number of | 1 | 123.06 | 10.73 | 91.28 | 95.78 |
| Example 1 | measurements | | | | | |

Referring to the results in Table 1, the third adhesive layers of Examples 1 to 4 have a creep value of from about 56.34% to about 106.48%, a residual strain of from about 1.34% to about 6.56%, and a recovery rate of from about 93.28% to about 97.62%. The third adhesive layer of Comparative Example 1 had a creep value of 123.06%, a residual strain of 10.73%, and a recovery rate of 91.28%.

It is confirmed that the third adhesive layers of Examples 1 to 4 have lower creep values, lower residual strains, and higher recovery rates than the third adhesive layer of Comparative Example 1 at high temperature and high humidity.

The third adhesive layer of the inventive concept satisfies the creep value (%), residual strain (%), and recovery rate (%) as shown in Table 1 when a torque of 943.9 μN·m is applied at high temperature and high humidity. For example, in the third adhesive layer of the inventive concept, at 60° C. and a relative humidity of from about 89% to about 96%, when a torque of 943.9 μN·m is applied to the third adhesive layer for 10 minutes, the third adhesive layer has a creep value of from about 50% to about 120%, a residual strain of from about 1.0% to about 9%, and a recovery rate of from about 92% to about 99%.

The third adhesive layer of the inventive concept satisfies data values described in Examples of Table 1, and satisfies data according to the conditions of Tables 2 to 6 below as well.

In Table 2, the creep value, residual strain, and recovery rate of the third adhesive layer are shown, which are measured at a torque of 200 μN·m which is applied to the third adhesive layers of Examples 5 to 8 and Comparative Example 2 in the test environment of 60° C. and a relative humidity of from about 89% to about 96%. Table 2 is a measurement of the creep values, residual strains, and recovery rates of the third adhesive layers of Examples 5 to 8 and Comparative Example 2.

TABLE 2

| | | | Creep value | Residual strain | Recovery rate | |
|---|---|---|---|---|---|---|
| Item | | | (%) | (%) | (%) | Humidity |
| Example 5 | Number of | 1 | 18.45 | 0.88 | 95.25 | 94.51 |
| | measurements | 2 | 18.79 | 0.74 | 96.06 | 94.43 |
| | | 3 | 19.77 | 0.83 | 95.82 | 95.57 |
| Example 6 | Number of | 1 | 20.37 | 1.16 | 94.29 | 93.23 |
| | measurements | 2 | 21.11 | 1.26 | 94.05 | 94.82 |
| | | 3 | 19.90 | 1.09 | 94.54 | 93.49 |
| Example 7 | Number of | 1 | 13.78 | 0.29 | 97.89 | 94.31 |
| | measurements | 2 | 13.22 | 0.32 | 97.54 | 94.29 |
| | | 3 | 13.35 | 0.29 | 97.84 | 94.93 |
| Example 8 | Number of | 1 | 13.49 | 0.33 | 97.57 | 95.12 |
| | measurements | 2 | 13.14 | 0.29 | 97.81 | 94.15 |
| | | 3 | 13.52 | 0.27 | 97.97 | 94.65 |
| Comparative | Number of | 1 | 26.09 | 1.89 | 92.77 | 95.05 |
| Example 2 | measurements | 2 | 23.99 | 1.69 | 92.95 | 94.61 |
| | | 3 | 23.58 | 1.60 | 93.20 | 94.65 |

Referring to the results in Table 2, the third adhesive layers of Examples 5 to 8 have a creep value of from about 13.14% to about 21.11%, a residual strain of about 0.27% to about 1.26%, and a recovery rate of from about 94.05% to about 97.97%.

The third adhesive layer of Comparative Example 2 has a creep value of from about 23.58% to about 26.09%, a residual strain of from about 1.60% to about 1.89%, and a recovery rate of from about 92.77% to about 93.20%.

The third adhesive layers of Examples 5 to 8 have lower creep values, lower residual strains, and higher recovery rates than the third adhesive layer of Comparative Example 2 at high temperature and high humidity. Accordingly, the display device according to an embodiment of the inventive concept may have excellent reliability at a high temperature of 60° C. and a high relative humidity of from about 89% to about 96%.

In Table 3, the creep value, residual strain, and recovery rate of the third adhesive layer are shown, which are measured at a torque of 2000 μN·m which is applied to the third adhesive layers of Examples 9 to 12 and Comparative Example 3 at 60° C. and a relative humidity of from about 89% to about 96%. Table 3 is a measurement of the creep values, residual strains, and recovery rates of the third adhesive layers of Examples 9 to 12 and Comparative Example 3.

TABLE 3

| | | | Creep value | Residual strain | Recovery rate | |
|---|---|---|---|---|---|---|
| Item | | | (%) | (%) | (%) | Humidity |
| Example 9 | Number of | 1 | 253.52 | 26.66 | 89.48 | 92.92 |
| | measurements | 2 | 229.02 | 13.89 | 93.94 | 92.13 |
| | | 3 | 242.99 | 23.89 | 90.17 | 93.99 |
| Example 10 | Number of | 1 | 294.19 | 45.70 | 84.46 | 92.76 |
| | measurements | 2 | 276.09 | 31.35 | 88.65 | 94.26 |
| | | 3 | 296.73 | 43.43 | 85.36 | 94.22 |
| Example 11 | Number of | 1 | 135.04 | 7.30 | 94.59 | 92.23 |
| | measurements | 2 | 151.18 | 21.97 | 85.47 | 93.05 |
| | | 3 | 134.64 | 8.96 | 93.34 | 94.89 |
| Example 12 | Number of | 1 | 129.13 | 6.94 | 94.63 | 93.89 |
| | measurements | 2 | 134.13 | 11.19 | 91.65 | 94.27 |
| | | 3 | 134.47 | 10.20 | 92.42 | 94.16 |
| Comparative | Number of | 1 | 562.41 | 264.86 | 52.91 | 94.09 |
| Example 3 | measurements | | | | | |

Referring to the results in Table 3, the third adhesive layers of Examples 9 to 12 have a creep value of from about 129.13% to about 296.73%, a residual strain of from about 6.94% to about 45.7%, and a recovery rate of from about 84.46% to about 94.63%.

The third adhesive layer of Comparative Example 3 has a creep value of 562.41%, a residual strain of 264.86%, and a recovery rate of 52.91%.

The third adhesive layers of Examples 9 to 12 have lower creep values, lower residual strains, and higher recovery rates than the third adhesive layer of Comparative Example 3 at high temperature and high humidity.

In Table 4, the creep value, residual strain, and recovery rate of the third adhesive layer are shown, which are measured at a torque of 2300 μN·m which is applied to the third adhesive layers of Examples 13 to 16 and Comparative Example 4 at 60° C. and a relative humidity of from about 89% to about 96%. Table 4 is a measurement of the creep values, residual strains, and recovery rates of the third adhesive layers of Examples 13 to 16 and Comparative Example 4.

TABLE 4

| | | | Creep value | Residual strain | Recovery rate | |
|---|---|---|---|---|---|---|
| Item | | | (%) | (%) | (%) | Humidity |
| Example 13 | Number of | 1 | 315.79 | 56.36 | 82.15 | 89.63 |
| | measurements | 2 | 378.30 | 107.96 | 71.46 | 94.77 |
| | | 3 | 365.57 | 93.10 | 74.53 | 94.48 |
| Example 14 | Number of | 1 | 343.08 | 47.17 | 86.25 | 91.11 |
| | measurements | 2 | 339.64 | 63.77 | 81.22 | 93.19 |
| | | 3 | 377.55 | 83.36 | 77.92 | 94.2 |
| Example 15 | Number of | 1 | 229.51 | 52.12 | 77.29 | 94.47 |
| | measurements | 2 | 218.60 | 39.44 | 81.96 | 94.53 |
| | | 3 | 203.90 | 29.72 | 85.42 | 93.46 |
| Example 16 | Number of | 1 | 178.87 | 12.48 | 93.02 | 93.46 |
| | measurements | 2 | 188.80 | 16.25 | 91.39 | 94.17 |
| | | 3 | 192.04 | 19.65 | 89.77 | 95.36 |
| Comparative | Number of | 1 | 1036.01 | 630.78 | 39.11 | 94.31 |
| Example 4 | measurements | | | | | |

Referring to the results in Table 4, the third adhesive layers of Examples 13 to 16 have a creep value of from about 178.87% to about 378.30%, a residual strain of from about 12.48% to about 107.96%, and a recovery rate of from about 71.46% to about 93.02%. The third adhesive layer of Comparative Example 4 has a creep value of 1036.01%, a residual strain of 630.78%, and a recovery rate of 39.11%. The third adhesive layers of Examples 13 to 16 have lower creep values, lower residual strains, and higher recovery rates than the third adhesive layer of Comparative Example 4 at high temperature and high humidity.

Referring to Tables 1 to 4 together, the third adhesive layers of Examples 1 to 16 had lower creep values, lower residual strains, and higher recovery rates than the third adhesive layers of Comparative Examples 1 to 4.

In Table 5, the creep value, residual strain, and recovery rate of the third adhesive layer are shown, which are measured at a torque of 200 μN·m which is applied to the third adhesive layers of each of Examples 17 to 20 at 25° C. and a relative humidity of from about 40% to about 50%. Table 5 is a measurement of the creep values, residual strains, and recovery rates of the third adhesive layers of each of Examples 17 to 20.

TABLE 5

| | | | Creep | Residual | Recovery |
|---|---|---|---|---|---|
| Item | | | value (%) | strain (%) | rate (%) |
| Example 17 | Number of | 1 | 15.84 | 1.14 | 92.80 |
| | measurements | 2 | 16.60 | 1.31 | 92.10 |
| | | 3 | 15.89 | 1.32 | 91.72 |
| Example 18 | Number of | 1 | 17.89 | 1.60 | 91.03 |
| | measurements | 2 | 18.30 | 1.64 | 91.05 |
| | | 3 | 19.52 | 1.68 | 91.41 |
| Example 19 | Number of | 1 | 11.72 | 0.58 | 95.01 |
| | measurements | 2 | 12.31 | 0.59 | 95.17 |
| | | 3 | 11.68 | 0.56 | 95.19 |
| Example 20 | Number of | 1 | 12.47 | 0.70 | 94.39 |
| | measurements | 2 | 12.61 | 0.67 | 94.71 |
| | | 3 | 12.28 | 0.69 | 94.41 |

Referring to the results in Table 5, the third adhesive layers of Examples 17 to 20 have a creep value of from about 11.68% to about 19.52%, a residual strain of from about 0.56% to about 1.68%, and a recovery rate of from about 91.03% to about 95.19%.

In Table 6, the creep value, residual strain, and recovery rate of the third adhesive layer are measured at a torque of 200 μN·m which is applied to the third adhesive layers of each of Examples 21 to 24 at 60° C. and a relative humidity of from about 40% to about 50%. Table 6 is a measurement of the creep values, residual strains, and recovery rates of the third adhesive layers of each of Examples 21 to 24.

TABLE 6

| | | | Creep | Residual | Recovery |
|---|---|---|---|---|---|
| Item | | | value (%) | strain (%) | rate (%) |
| Example 21 | Number of | 1 | 19.06 | 0.96 | 94.95 |
| | measurements | 2 | 19.75 | 0.87 | 95.60 |
| | | 3 | 19.34 | 0.75 | 96.14 |
| Example 22 | Number of | 1 | 22.92 | 1.61 | 92.98 |
| | measurements | 2 | 21.17 | 1.10 | 94.81 |
| | | 3 | 21.72 | 1.27 | 94.17 |
| Example 23 | Number of | 1 | 13.60 | 0.45 | 96.72 |
| | measurements | 2 | 13.28 | 0.35 | 97.39 |
| | | 3 | 13.37 | 0.38 | 97.19 |
| Example 24 | Number of | 1 | 13.34 | 0.31 | 97.70 |
| | measurements | 2 | 13.26 | 0.37 | 97.20 |
| | | 3 | 13.34 | 0.36 | 97.27 |

Referring to the results in Table 6, the third adhesive layers of Examples 21 to 24 have a creep value of from about 13.26% to about 22.92%, a residual strain of from about 0.31% to about 1.61%, and a recovery rate of from 92.98% to 97.70%. In Tables 7 to 10 below, storage modulus G′, loss elastic modulus G″, and tan delta tan δ of the third adhesive layers are measured. The storage modulus G′ may refer to elasticity of an adhesive layer, and the loss elastic modulus G″ may refer to a fluid property of an adhesive layer. The tan delta tan δ may be defined as a value of the loss elastic modulus G″/storage modulus G′. For example, the tan delta tan δ may be a value obtained when the loss elastic modulus G″ is divided by the storage modulus G′.

The storage modulus G′ and the loss elastic modulus G″ are measured at a heating rate of 10° C./min under the condition that a frequency of 1 Hz and an axial force of 1.0 N are applied to the adhesive layer in a rheometer. In such measurement, the adhesive layer may be kept at a strain of 1%.

Table 7 shows storage modulus G′, loss elastic modulus G″, and tan delta tan δ values of each of the third adhesive layers in Examples 25 to 28 which are measured at −20° C. The temperature of −20° C. may be defined as low temperature.

TABLE 7

| Item | | | G′( [symbol] Pa) | G″( [symbol] Pa) | tan δ |
|---|---|---|---|---|---|
| Example 25 | Number of | 1 | 121243 | 84772 | 0.699 |
| | measurements | 2 | 117173 | 101543 | 0.867 |
| | | 3 | 115671 | 93245 | 0.806 |
| Example 26 | Number of | 1 | 125823 | 102337 | 0.813 |
| | measurements | 2 | 131776 | 108378 | 0.822 |
| | | 3 | 126144 | 107660 | 0.853 |
| Example 27 | Number of | 1 | 124630 | 100952 | 0.810 |
| | measurements | 2 | 122832 | 124732 | 1.015 |
| | | 3 | 121954 | 88384 | 0.725 |
| Example 28 | Number of | 1 | 113980 | 91224 | 0.800 |
| | measurements | 2 | 127516 | 98370 | 0.771 |
| | | 3 | 119879 | 92244 | 0.769 |

Referring to the results in Table 7, the third adhesive layers of Examples 25 to 28 may have storage modulus G′ of from about 0.113980 MPa to about 0.131776 MPa, loss elastic modulus G″ of from about 0.084772 MPa to about 0.124732 MPa, and tan delta tan δ of 0.699 to 1.015 at −20° C. The storage modulus G′ and loss elastic modulus G″ of each of the third adhesive layers of Examples 25 to 28 are about 0.01 MPa to about 0.2 MPa at −20° C. The storage modulus G′ and loss elastic modulus G″ of each of the third adhesive layers of Examples 25 to 28 have a similar range of values at −20° C.

Table 8 shows storage modulus G′, loss elastic modulus G″, and tan delta tan δ values of each of the third adhesive layers in Examples 29 to 32 which are measured at 25° C. The temperature of 25° C. may be defined as room temperature.

TABLE 8

| Item | | | G′( [symbol] Pa) | G″( [symbol] Pa) | tan δ |
|---|---|---|---|---|---|
| Example 29 | Number of | 1 | 39620 | 10416 | 0.263 |
| | measurements | 2 | 39315 | 10736 | 0.273 |
| | | 3 | 40696 | 10726 | 0.264 |
| Example 30 | Number of | 1 | 40251 | 10127 | 0.252 |
| | measurements | 2 | 40796 | 10767 | 0.264 |
| | | 3 | 38020 | 9471 | 0.249 |
| Example 31 | Number of | 1 | 40501 | 9328 | 0.230 |
| | measurements | 2 | 41016 | 10078 | 0.246 |
| | | 3 | 40278 | 10475 | 0.260 |
| Example 32 | Number of | 1 | 38977 | 10321 | 0.265 |
| | measurements | 2 | 40243 | 10458 | 0.260 |
| | | 3 | 38564 | 9655 | 0.250 |

Referring to the results in Table 8, the third adhesive layers of Examples 29 to 32 may have storage modulus G′ of from about 0.038020 MPa to about 0.041016 MPa, loss elastic modulus G″ of from about 0.009328 MPa to about 0.010767 MPa, and tan delta tan δ of 0.23 to 0.273 at 25° C. The storage modulus G′ of the third adhesive layers of Examples 29 to 32 at 25° C. is greater than the loss elastic modulus G″ thereof. Accordingly, the tan delta tan δ value at −25° C. may be smaller than the tan delta tan δ value at −20° C.

Table 9 shows storage modulus G′, loss elastic modulus G″, and tan delta tan δ values of each of the third adhesive layers in Examples 33 to 36 which are measured at 60° C. The temperature of 60° C. may be defined as a high temperature.

TABLE 9

| Item | | | G′( [symbol] Pa) | G″( [symbol] Pa) | tan δ |
|---|---|---|---|---|---|
| Example 33 | Number of | 1 | 29020 | 7794 | 0.269 |
| | measurements | 2 | 27984 | 7636 | 0.273 |
| | | 3 | 28613 | 8137 | 0.284 |
| Example 34 | Number of | 1 | 29438 | 8047 | 0.273 |
| | measurements | 2 | 28276 | 8042 | 0.284 |
| | | 3 | 26621 | 7504 | 0.282 |
| Example 35 | Number of | 1 | 30170 | 7009 | 0.232 |
| | measurements | 2 | 30014 | 7465 | 0.249 |
| | | 3 | 29812 | 7292 | 0.245 |
| Example 36 | Number of | 1 | 28721 | 6946 | 0.242 |
| | measurements | 2 | 28900 | 7041 | 0.244 |
| | | 3 | 29502 | 7073 | 0.240 |

Referring to the results in Table 9, the third adhesive layers of Examples 33 to 36 may have storage modulus G′ of from about 0.026621 MPa to about 0.03017 MPa, loss elastic modulus G″ of from about 0.006946 MPa to about 0.008137 MPa, and tan delta tan δ of from 0.232 to 0.284 at 60° C. The storage modulus G′ of the third adhesive layers of Examples 33 to 36 at 60° C. is about three times greater than the loss elastic modulus G″. Accordingly, the tan delta tan δ value at 60° C. may be smaller than the tan delta tan δ value at −20° C.

Table 10 shows storage modulus G′, loss modulus G″, and tan delta tan δ values of each of the third adhesive layers in Examples 37 to 40 which are measured at 85° C. The temperature of 85° C. may be defined as a high temperature.

TABLE 10

| Item | | | G′( [symbol] Pa) | G″( [symbol] Pa) | tan δ |
|---|---|---|---|---|---|
| Example 37 | Number of | 1 | 23476 | 6592 | 0.281 |
| | measurements | 2 | 22931 | 6008 | 0.262 |
| | | 3 | 24488 | 6675 | 0.273 |
| Example 38 | Number of | 1 | 24595 | 6875 | 0.280 |
| | measurements | 2 | 23520 | 6931 | 0.295 |
| | | 3 | 22328 | 6364 | 0.285 |
| Example 39 | Number of | 1 | 25861 | 5388 | 0.208 |
| | measurements | 2 | 25733 | 5089 | 0.198 |
| | | 3 | 25927 | 6122 | 0.236 |
| Example 40 | Number of | 1 | 25046 | 5264 | 0.210 |
| | measurements | 2 | 25647 | 5432 | 0.212 |
| | | 3 | 25711 | 5352 | 0.208 |

Referring to the results in Table 10, the third adhesive layers of Examples 37 to 40 may have storage modulus G′ of from about 0.022328 MPa to about 0.025927 MPa, loss elastic modulus G″ of from about 0.005089 MPa to about 0.006931 MPa, and tan delta tan δ of from 0.198 to 0.295 at 85° C. The storage modulus G′ of the third adhesive layers of Examples 37 to 40 at 85° C. is about three times greater than the loss elastic modulus G″. Accordingly, the tan delta tan δ at 85° C. value may be smaller than the tan delta tan δ value at −20° C.

At room temperature and high temperature, when the storage modulus G′ is relatively greater than the loss elastic modulus G″, the adhesive layer may better keep the elastic property. When the tan delta tan δ value defined as the loss modulus/storage modulus is smaller, the adhesive layer may have better elastic property.

Referring to Tables 7 to 10 together, the third adhesive layer according to an embodiment of the inventive concept has the storage modulus G′ greater than the loss elastic modulus G″, and a small tan delta tan δ value at room temperature and high temperature. Accordingly, the third adhesive layer may keep the elastic property—at a high temperature and may have high recovery property.

Meanwhile, an anti-reflection layer RPL and a functional layer FNL may be disposed on the third adhesive layer AL3 of Tables 1 to 10. For example, the anti-reflection layer RPL may be disposed on the third adhesive layer AL3. The functional layer FNL may be disposed on the anti-reflection layer RPL.

In Table 11, Young's modulus, which is the physical property of the anti-reflection layer RPL that is a layer adjacent to the third adhesive layer AL3, is measured. The Young's modulus of the anti-reflection layer RPL is measured using a universal test machine (UTM 565) from Instron. Samples used are prepared according to ISO527-3 type 5. The present inventive concept is not limited thereto. For example, the values may be measured using a test machine from another equipment supplier.

In Table 11, the display device 1000 according to an embodiment includes a polarizing layer as the anti-reflection layer RPL.

TABLE 11

| | | | Young's modulus |
|---|---|---|---|
| | | | (MPa) of anti- |
| Temperature and/or Humidity condition | | | reflection layer |
| Low temperature | Number of | 1 | 9796 |
| −20° C. | measurements | 2 | 9674 |
| Room temperature | Number of | 1 | 8375 |
| 25° C. | measurements | 2 | 8354 |
| High temperature | Number of | 1 | 7046 |
| 60° C. | measurements | 2 | 6951 |
| High temperature and | Number of | 1 | 3200 |
| high humidity | measurements | | |
| (60° C. relative humidity 93%) | | 2 | 3320 |

In Table 12, the Young's modulus, which is the physical property of the functional layer FNL that is a layer adjacent to the third adhesive layer AL3, is shown. The Young's modulus of the functional layer FNL is measured using a universal test machine (UTM 565) from Instron. Samples used are prepared according to ISO527-3 type 5.

In Table 12, the display device 1000 according to an embodiment includes a shock absorbing layer containing polyethylene terephthalate (PET) as the functional layer FNL.

TABLE 12

| | | | | Young's modulus |
|---|---|---|---|---|
| | | | Tensile | (MPa)of functional |
| Temperature and/or Humidity condition | | | direction | layer |
| Low temperature | Number of | 1 | MD | 5838 |
| −20° C. | measurements | 2 | TD | 5740 |
| | | 3 | MD | 6439 |
| | | 4 | TD | 6519 |
| Room temperature | Number of | 1 | MD | 5177 |
| 25° C. | measurements | 2 | TD | 5166 |
| | | 3 | MD | 5764 |
| | | 4 | TD | 5805 |
| High temperature | Number of | 1 | MD | 4352 |
| 60° C. | measurements | 2 | TD | 4390 |
| | | 3 | MD | 5053 |
| | | 4 | TD | 4925 |
| High temperature and | Number of | 1 | MD | 3990 |
| high humidity | measurements | 2 | TD | 3925 |
| (60° C. relative | | 3 | MD | 4617 |
| humidity 93%) | | 4 | TD | 4577 |

(Evaluation 2 of Adhesive Layer Properties)

In the evaluation of the adhesive layer properties of an embodiment, the amount of a photo initiator and a creep value of the third adhesive layer according to an embodiment of the inventive concept are measured. For example, the third adhesive layer may be a pressure sensitive adhesive film (PSA). The photo initiator may be included in the preparation process of the third adhesive layer. For example, the photo initiator may include or may be formed of a methyl benzoate-based material.

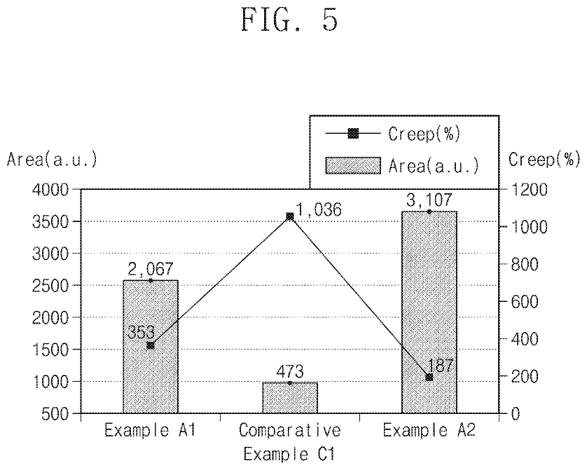

FIG. 5 is a graph showing creep values and an initiator amount contained in the third adhesive layer of each of Examples A1 and A2, and Comparative Example C1, as an example, at 60° C. and a humidity of 93% according to an embodiment of the present inventive concept.

Referring to FIG. 5, the right y-aix of the graph shows a creep value. The left y-aix of the graph shows an area value of a bar graph. The area value of the bar graph indicates an amount of the photo initiator contained in the third adhesive layer relatively. The unit of the area value of the bar graph is an arbitrary unit (a.u.).

The third adhesive layers of Examples A1 and A2 described in FIG. 5 have photo initiators at an amount of about 2,067 and about 3,107, respectively. The third adhesive layer of Comparative Example C1 has a photo initiator at an amount of 473. The amount of the photo initiator contained in the third adhesive layer of Comparative Example C1 is a fourth or less of the amount of the photo initiator contained in the third adhesive layer of Examples A1 and A2.

Examples A1 and A2 have measured creep values of about 353% and about 187%, respectively, and Comparative Example C1 has a measured creep value of 1036%. The creep value of Comparative Example C1 is at least about three times greater than the creep values of Examples A1 and A2.

Referring to the measured amounts of photo initiators and creep values together, the third adhesive layers of Examples A1 and A2 have a greater amount of photo initiators than the third adhesive layer of Comparative Example C1, and the creep values may be reduced. It is understood that with an increase in the amount of the photo initiator, cross linking in the adhesive layer may increase, and thus the adhesive layer has a greater value of elastic modulus and recovery rate, and a lower creep value.

The third adhesive layer according to an embodiment of the inventive concept may have high elasticity, a low strain, and a high recovery rate even at a low temperature, room temperature, high temperature, and high temperature and high humidity. Accordingly, regardless of the conditions according to temperature and humidity around the display device, the elastic and recovery properties of the adhesive layer may be easily kept. The display device according to an embodiment of the inventive concept may have high reliability due to reduced defects such as peeling of the adhesive layer.

A display device according to an embodiment of the inventive concept may include an adhesive layer having high elasticity, a low strain, and a high recovery rate. Accordingly, when a pressing process is performed or when the display device is repeatedly folded, adhesive layer may easily keep the elastic and recovery properties and be less deformed.

Although the inventive concept has been described with reference to embodiments of the inventive concept, it will be understood that various changes and modifications can be made by those skilled in the art without departing from the spirit and scope of the inventive concept. In addition, the embodiments disclosed in the inventive concept are not intended to limit the technical spirit of the inventive concept, and the scope of the disclosure is not to be limited by the above embodiments but by the claims and the equivalents thereof.

What is claimed is:

1. A display device comprising:
a display module;
an anti-reflection layer disposed on the display module; and
an adhesive layer disposed between the display module and the anti-reflection layer,
wherein, at 60° C. and a relative humidity of from about 89% to about 96%, when a torque of 943.9 μN·m is applied to the adhesive layer for 10 minutes, the adhesive layer has a creep value of from about 50% to about 120%, and
wherein at 60° C. and a relative humidity of from about 89% to about 96%, the anti-reflection layer has a Young's modulus value of from about 3000 MPa to about 5000 MPa.

2. The display device of claim 1,
wherein, 10 minutes after the torque of 943.9 μN·m applied to the adhesive layer is removed, the adhesive layer has a residual strain of from about 1.0% to about 9%, and a recovery rate of from about 92% to about 99%.

3. The display device of claim 1,
wherein, when a torque of 200 μN·m is applied to the adhesive layer for 10 minutes, the adhesive layer has a creep value of from about 10% to about 23%.

4. The display device of claim 3,
wherein, 10 minutes after the torque of 200 μN·m applied to the adhesive layer is removed, the adhesive layer has a residual strain of about 0.1% to about 1.5%, and a recovery rate of from about 94% to about 99%.

5. The display device of claim 1,
wherein, when a torque of 2000 μN·m is applied to the adhesive layer for 10 minutes, the adhesive layer has a creep value of from about 90% to about 400%.

6. The display device of claim 5,
wherein, 10 minutes after the torque of 2000 μN·m applied to the adhesive layer is removed, the adhesive layer has a residual strain of from about 4% to about 100%, and a recovery rate of from about 70% to about 99%.

7. The display device of claim 1,
wherein, when a torque of 2300 μN·m is applied to the adhesive layer for 10 minutes, the adhesive layer has a creep value of from about 100% to about 600%.

8. The display device of claim 7,
wherein, 10 minutes after the torque of 2300 μN·m applied to the adhesive layer is removed, the adhesive layer has a residual strain of from about 8% to about 200%, and a recovery rate of from about 40% to about 99%.

9. The display device of claim 1, wherein:
at 25° C. and a relative humidity of from about 40% to about 50%, when a torque of 200 μN·m is applied to the adhesive layer for 10 minutes, the adhesive layer has a creep value of from about 5% to about 30%; and
at 25° C., the anti-reflection layer has a Young's modulus value of from about 9000 MPa to about 9000 MPa.

10. The display device of claim 9,
wherein, at 25° C. and a relative humidity of from about 40% to about 50%, 10 minutes after the torque of 200 μN·m applied to the adhesive layer is removed, the adhesive layer has a residual strain of from about 0.1% to about 2.5%, and a recovery rate of from about 85% to about 99%.

11. The display device of claim 1, wherein:
at 60° C. and a relative humidity of from about 40% to about 50%, when a torque of 200 μN·m is applied to the adhesive layer for 10 minutes, the adhesive layer has a creep value of from about 8% to about 30%; and
at 60° C. and a relative humidity of from about 40% to about 50%, the anti-reflection layer has a Young's modulus value of from about 5000 MPa to about 8000 MPa.

12. The display device of claim 11,
wherein, at 60° C. and a relative humidity of from about 40% to about 50%, 10 minutes after the torque of 200 μN·m applied to the adhesive layer is removed, the adhesive layer has a residual strain of from about 0.1% to about 3%, and a recovery rate of from about 85% to about 99%.

13. The display device of claim 1,
wherein when a frequency of 1 Hz and an axial force of 1.0 N are applied to the adhesive layer and the adhesive layer is kept at a strain of 1%, the adhesive layer, at −20° C., has a storage modulus value of from about 0.01 MPa to about 0.2 MPa, a loss elastic modulus value of from about 0.01 MPa to about 0.2 MPa, and a tan delta value of from about 0.5 to about 1.2, the tan delta value being defined as a value of a loss modulus value divided by a storage modulus value, and at −20° C., the anti-reflection layer has a Young's modulus value of from about 9000 MPa to about 11000 MPa.

14. The display device of claim 1,
wherein when a frequency of 1 Hz and an axial force of 1.0 N are applied to the adhesive layer and the adhesive layer is kept at a strain of 1%, the adhesive layer, at 25° C., has a storage modulus value of from about 0.01 MPa to about 0.1 MPa, a loss elastic modulus value of from about 0.001 MPa to about 0.05 MPa, and a tan delta value of from about 0.1 to about 0.4, the tan delta value being defined as a loss modulus value/a storage modulus value, and at 25° C., the anti-reflection layer has a Young's modulus value of from about 8000 MPa to about 9000 MPa.

15. The display device of claim 1,
wherein when a frequency of 1 Hz and an axial force of 1.0 N are applied to the adhesive layer and the adhesive layer is kept at a strain of 1%, the adhesive layer, at 60° C., has a storage modulus value of from about 0.01 MPa to about 0.04 MPa, a loss elastic modulus value of from about 0.001 MPa to about 0.01 MPa, and a tan delta value of about 0.1 to about 0.4, the tan delta value being defined as a loss modulus value/a storage modulus value, and at 60° C. and a relative humidity of from about 40% to about 50%, the anti-reflection layer has a Young's modulus value of from about 5000 MPa to about 8000 MPa.

16. The display device of claim 1,
wherein when a frequency of 1 Hz and an axial force of 1.0 N are applied to the adhesive layer and the adhesive layer is kept at a strain of 1%, the adhesive layer, at 85° C., has a storage modulus value of from about 0.01 MPa to about 0.05 MPa, a loss elastic modulus value of from about 0.001 MPa to about 0.01 MPa, and a tan delta value of from about 0.1 to about 0.4, the tan delta value being defined as a loss modulus value/a storage modulus value, and at 85° C., the anti-reflection layer has a Young's modulus value of 3000 MPa or less.

17. The display device of claim 1,
wherein the adhesive layer comprises a silicone-based resin, an acrylic resin, or a urethane-based resin, and has a thickness of from about 10 μm to about 70 μm.

18. The display device of claim 1,
wherein the adhesive layer is in contact with each of the display module and the anti-reflection layer.

19. The display device of claim 1, further comprising:
a shock absorbing layer and a window disposed on the anti-reflection layer,
wherein the shock absorbing layer includes a resin, and the window includes glass.

20. The display device of claim 1,
wherein the anti-reflection layer is a polarizing layer.
